(19) United States
(12) Patent Application Publication
(10) Pub. No.: US 2006/0267104 A1
(43) Pub. Date: Nov. 30, 2006

(54) Thyristor with integrated resistance and method for producing it

(75) Inventors: Detlef Scholz, Soest (DE); Uwe Kellner-Werdehausen, Leutenbach (DE); Franz-Josef Niedernostheide, Muenster (DE); Hans-Joachim Schulze, Ottobrunn (DE); Carsten Schneider, Willingen (DE)

Correspondence Address: BAKER BOTTS, L.L.P., 98 SAN JACINTO BLVD., SUITE 1500, AUSTIN, TX, 78701-4039, US

(73) Assignee: Infineon Technologies AG

(21) Appl. No.: 11/315,976

(22) Filed: Dec. 21, 2005

(30) Foreign Application Priority Data
Dec. 23, 2004 (DE) 10 2004 062 183.7

(51) Int. Cl. H01L 29/76

(52) U.S. Cl. 257/379

(57) ABSTRACT

A thyristor has a semiconductor body (1), in which a p-doped emitter (8), an n-doped base (7), a p-doped base (6) and an n-doped main emitter (5) are arranged successively in a vertical direction, the p-doped base (6) having a resistance zone (65) with a predetermined electrical resistance (R.int) extending in a lateral direction (r) perpendicular to the vertical direction, an external resistor (30, R.ext) that is arranged or can be arranged outside the semiconductor body (1) being electrically connected in parallel with the resistance zone (65), and the external resistor (30) having, in a specific temperature range, a temperature coefficient whose magnitude is less than the magnitude of the temperature coefficient of the resistance zone (65) in the specific temperature range.

### CROSS REFERENCE TO RELATED APPLICATION

This application claims priority from German Patent Application No. DE 10 2004 062 183.7 which was filed on Dec. 23, 2004 and is incorporated herein by reference in its entirety.

### TECHNICAL FIELD

The invention relates to a thyristor, in particular a thyristor with a triggering stage structure, which has an integrated protective resistance arranged in the p-doped base of the thyristor.

### BACKGROUND

The triggering stage structure of a thyristor of this type comprises one or more triggering stages that are arranged successively and ensure that the thyristor is switched on in controlled fashion. To avoid destroying the triggering stage structure when the thyristor is switched on a protective resistance is provided which is formed from a section of the p-doped base and is therefore integrated into the semiconductor body. Such a protective resistance is disclosed in DE 199 47 036 C1, for example. The section of the p-doped base that forms the protective resistance is also referred to hereinafter as resistance zone.

However, protective resistances of this type are greatly temperature-dependent. At temperatures below 400 K, this temperature dependence is essentially determined by the mobility of the charge carriers in the resistance zone. Since the number of phonons generated in the semiconductor body of the thyristor rises as the temperature increases, and since the charge carriers of the resistance zone are scattered at phonons, as the temperature increases this gives rise to a decrease in the mobility of the charge carriers in the semiconductor body and in particular also in the resistance zone, which is accompanied by an increase in the electrical resistance of the resistance zone.

An opposite effect consists in the fact that as the temperature increases in the semiconductor body of the thyristor, in particular in the resistance zone, more and more thermal charge carriers are generated, which leads to a reduction of the resistance value particularly in the resistance zone.

The two effects are superimposed, so that the influence of the phonon scattering is predominant at temperatures of typically below 400 K and the influence of the thermally generated charge carriers is predominant at temperatures above 400 K, so that the electrical resistance of the resistance zone increases with increasing temperature up to approximately 400 K and decreases with increasing temperature for temperatures of greater than 400 K.

Due to the thermal dependence of the protective resistance, it is difficult to limit the switch-on current in the triggering stage structure to a defined value during triggering of the thyristor. Particularly at very high temperatures, the triggering stage structure may be destroyed when the thyristor is switched on if the electrical protective resistance of the resistance zone—which limits the triggering current—falls below a permissible minimum value. This holds true primarily when the resistance zone forming the protective resistance undergoes transition to the state of intrinsic conduction on account of its high temperature.

In accordance with DE 196 40 311 A1, one possibility of reducing the temperature dependence of the protective resistance consists in generating scattering centres in the region of the resistance zone, for example by irradiating the resistance zone with helium ions, whilst simultaneously raising the doping concentration in the region of the resistance zone.

In order, however, to achieve a noticeable reduction of the temperature dependence, relatively high irradiation doses are required. However, the irradiation doses cannot be chosen to be arbitrarily high since, on the other hand, the leakage current of the thyristor would rise to an excessively great extent.

### SUMMARY

Therefore, the object of the present invention is to provide a thyristor whose protective resistance has a reduced temperature dependence, and also a method for producing such a thyristor.

This object can be achieved by means of a thyristor comprising a semiconductor body, wherein a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction, and an external resistor arranged outside the semiconductor body and electrically connected in parallel with the resistance zone, the external resistor and the resistance zone in each case having a temperature coefficient, and, in a specific temperature range, the magnitude of the temperature coefficient of the external resistor being less than the magnitude of the temperature coefficient of the resistance zone.

The temperature coefficient of the external resistor and the temperature coefficient of the resistance zone may have different signs in the specific temperature range. The temperature range may extend from 300 K to 450 K. The external resistor can be constant in the temperature range of between 300 K and 450 K or may not deviate more than 50% from its value at 300 K. The resistance zone and the external resistor electrically connected in parallel therewith may have a total resistance which, in the temperature range of between 300 K and 450 K, deviates by at most 50% from its value at 300 K. The resistance zone and the external resistor electrically connected in parallel therewith may have a total resistance which, in the temperature range of between 300 K and 450 K, deviates by at most 30% from its value at 300 K. The resistance zone and the external resistor electrically connected in parallel therewith may also have a total resistance which amounts to between 10Ω and 500Ω at a temperature of 293 K. The resistance zone and the external resistor electrically connected in parallel therewith may also have a total resistance which amounts to between 80Ω and 120Ω at a temperature of 293 K. The resistance zone may have an electrical resistance which amounts to between 20Ω and 1000Ω at a temperature of 293 K. The external resistor may comprise at least one of the materials constantan, manganin or polycrystalline silicon or is formed as a carbon composition resistor. The mobility of the charge carriers in the resistance zone can be reduced on account of particles being radiated into the resistance zone. In a section of the n-doped base that is arranged below the resistance zone, the mobility of the charge carriers can be reduced on account of particles being radiated into the section of the n-doped base. The external resistor can be arranged on the semiconductor body and can be fixedly connected to the latter. The external resistor can be arranged on a ceramic element. The thyristor may further comprise a housing, in which the semiconductor body is arranged, the external resistor being arranged outside the housing.

The object can also be achieved by a thyristor comprising a semiconductor body, wherein a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction, two connection locations for making electrical contact with the resistance zone, the connection locations being spaced apart from one another in the lateral direction, and a housing enclosing the semiconductor body, from which housing are led two connection contacts, each of which are electrically conductively connected to a respective one of the connection locations and which are provided for the connection of an external resistor arranged outside the housing.

The resistance zone may have an electrical resistance which amounts to between 20Ω and 1000Ω at a temperature of 293 K. An external electrical resistor can be connected to the connection contacts and is electrically connected in parallel with the resistance zone. The resistance zone may have an electrical resistance which amounts to between 20Ω and 1000Ω at a temperature of 293 K. The mobility of the charge carriers in the resistance zone can be reduced on account of particles being radiated into the resistance zone. In a section of the n-doped base that is arranged below the resistance zone, the mobility of the charge carriers can be reduced on account of particles being radiated into the section of the n-doped base.

The object can further be achieved by a method for producing a thyristor, comprising the following method steps of providing a semiconductor body, in which a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction, and connecting an external electrical resistor arranged outside the semiconductor body in parallel with the resistance zone, so that the resistance zone and the external resistor form a total electrical resistance which, in a specific temperature range, has a temperature coefficient whose magnitude is less than the temperature coefficient of the resistance zone in the temperature range.

The external resistor may have, in the specific temperature range, a temperature coefficient whose magnitude is less than the temperature coefficient of the resistance zone in the temperature interval. The temperature range may extend from 300 K to 450 K. The electrical resistance of the resistance zone can be increased. For the purpose of increasing the electrical resistance of the resistance zone particles can be radiated into the resistance zone. Particles can be radiated into a section of the n-doped base that is arranged below the resistance zone. The electrical resistance of the resistance zone can be reduced.

A thyristor according to the invention, thus, comprises a semiconductor body, in which a p-doped emitter, an n-doped base, a p-doped base and an n-doped main emitter are arranged successively in a vertical direction. A resistance zone with a predetermined electrical resistance arranged in the p-doped base extends in a lateral direction r perpendicular to the vertical direction. In this case, the expression “lateral” also includes the term “radial”, which is often used preferably in the case of rotationally symmetrically or at least substantially rotationally symmetrically constructed thyristors.

An external resistor, typically arranged outside the semiconductor body, is electrically connected in parallel with the resistance zone, the external resistor having, at least in a specific temperature range, a temperature coefficient whose magnitude is less than the magnitude of the temperature coefficient of the resistance zone in the specific temperature range.

This connection in parallel gives rise to a total resistance which exhibits a lower temperature dependence than the resistance of the resistance zone provided that the external resistor is chosen suitably with regard to its temperature behavior and/or with regard to its arrangement.

The semiconductor body has connection locations to which the external resistor is connected. In this case, the external resistor may be arranged on the semiconductor body and is fixedly connected to the latter. However, the external resistor may likewise also be arranged in a chamber of a housing enclosing the semiconductor body, the external resistor, for making contact with the semiconductor body, merely being pressed onto the semiconductor body, for example using spring contacts.

In accordance with a further preferred embodiment of the invention, a thyristor which has connection locations of this type and whose semiconductor body is enclosed by a housing may be provided with connection contacts which are led from the housing and are electrically conductively connected to a respective one of the connection locations. Consequently, there is the possibility of an external resistor arranged outside the housing being connected to the connection contacts. It is thereby possible, by way of example, to adapt the external resistor to individual requirements, e.g. to an operating temperature range of the thyristor that occurs in a specific application. An external resistor arranged outside the housing in this way may likewise be cooled or brought to a defined temperature by means of additional measures.

In accordance with a further aspect of the invention, the external resistor is thermally decoupled from the semiconductor body to the greatest possible extent and is thus temperature-independent.

Furthermore, the external resistor and the resistance zone may have temperature coefficients with different signs at least in a specific temperature range, e.g. between 300 K and 450 K, which, particularly in the case of a thermal (residual) coupling between the external resistor and the resistance zone, may bring about a reduced temperature dependence of the protective resistance in the temperature range under consideration. A positive temperature coefficient in the temperature range under consideration is preferably to be aimed at in the case of the external resistor.

If the temperature coefficients of the total resistance and of the internal resistance zone change their signs as the temperature increases, then the change in sign in the case of the temperature coefficient of the total resistance preferably occurs at a higher temperature than the change in sign in the case of the temperature coefficient of the internal resistance zone.

### BRIEF DESCRIPTION OF THE DRAWINGS

Preferred embodiments of a thyristor according to the invention are explained in more detail below with reference to the accompanying figures, in which:

FIG. 1 shows a section of a thyristor according to the invention with an external resistor connected in parallel with a resistance zone, in cross section,

FIG. 2 shows the profile of the resistance value of a protective resistance which, in accordance with FIG. 1, is formed by connecting an external resistor and a resistance zone in parallel, as a function of the temperature, in comparison with the profile of the resistance value of a conventional protective resistance formed merely from a resistance zone, as a function of the temperature,

FIG. 3 shows a thyristor according to the invention in which particles are introduced by irradiation into the resistance zone and into a section of the n-doped base that is arranged below the resistance zone, in cross section.

FIG. 4 shows a section of a thyristor according to the invention in which an external resistor formed as a film resistor and electrically connected in parallel with the resistance zone is arranged on the semiconductor body and is fixedly connected to the latter, in cross section,

FIG. 5a shows a section of a thyristor according to the invention in which an external resistor that is formed as a film resistor and is not fixedly connected to the semiconductor body is electrically connected in parallel with a resistance zone, in cross section,

FIG. 5b shows a cross section through a thyristor in accordance with FIG. 5a which is arranged in a housing,

FIG. 6a shows a cross section through a thyristor according to the invention which is arranged in a housing and has connection contacts which are led from the housing and by means of which an external resistor can be connected in parallel with the resistance zone, and

FIG. 6b shows an enlarged section of the thyristor in accordance with FIG. 6a in cross section.

In the figures, identical reference symbols designate identical parts with the same meaning.

### DETAILED DESCRIPTION

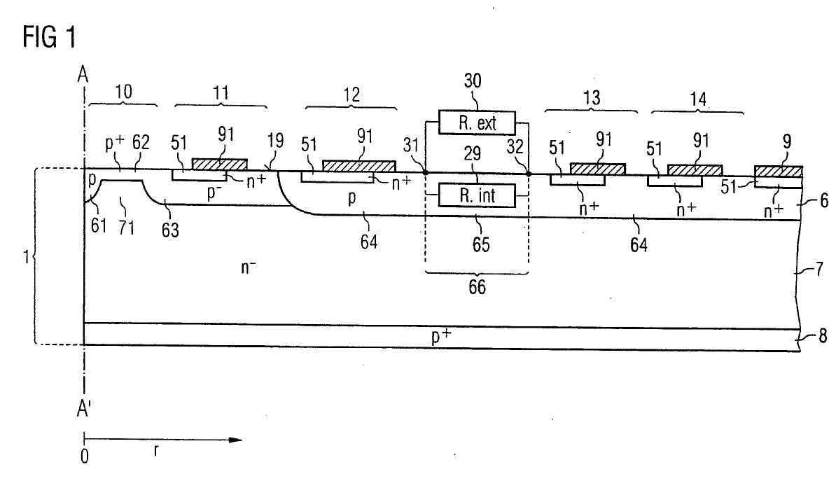

FIG. 1 shows a section of a thyristor according to the invention in cross section. In accordance with one preferred embodiment, the thyristor is constructed rotationally symmetrically or substantially rotationally symmetrically about an axis A-A′. It comprises a semiconductor body 1, in which a heavily p-doped emitter 8, a weakly n-doped base 7, a p-doped base 6 and a heavily n-doped main emitter 5 are arranged successively in a vertical direction. An emitter electrode 9 makes contact with the heavily n-doped main emitter 5. The p-doped base 6 comprises p-doped sections 61 and 64, a heavily p-doped section 62 and also a weakly p-doped section 63. The p-doped section 64 in turn comprises a section 65, which is also referred to below as resistance zone and the laterally effective resistance of which, by the application of suitable measures, may also be higher than that which would result if the resistivity of the zone 65 corresponded to that of the zone 64. Such measures may be, in addition to locally increasing the resistivity, e.g. the removal of a region of the resistance zone 65 near the surface or the local irradiation of the resistance zone 65 with particles. Since the semiconductor body 1 is preferably formed rotationally symmetrically about the axis A-A′, the resistance zone 65 preferably likewise has a rotational symmetry about the axis A-A′.

FIG. 1 symbolically illustrates an electrical resistor 29 representing the total electrical resistance R.int of the resistance zone 65.

In a section 71 of the weakly n-doped base 7, the latter extends between the sections 61 and 63 of the p-doped base 6 further in the direction of the front side 19 of the semiconductor body 1 into the p-doped base 6 than in the remaining regions of the n-doped base 7. A curved pn junction is in each case formed between the sections 61 and 63 of the p-doped base 6 and the section 71 of the n-doped base 7, so that the breakdown field strength is obtained in the centre (r=0) of the thyristor rather than in the remaining regions of the thyristor. The pn junction formed between the sections 61, 62 and 63 of the p-doped base 6 and the weakly n-doped base 7 is also referred to hereinafter as breakdown structure 10.

On account of the described geometry of the breakdown structure 10 and the associated profile of the electric field, with a rising voltage present in the forward direction, the thyristor triggers firstly in the region of the breakdown structure 10. Furthermore, a triggering of the thyristor may also be achieved by radiating light, in particular infrared light, onto the front side 19 of the semiconductor body 1 into the region of the breakdown structure 10. It is thereby possible to trigger the thyristor with light.

In order to achieve a controlled switch-on of the thyristor, one or more triggering stages are arranged in the lateral direction r between the breakdown structure 10 and the n-doped main emitter 5. Four triggering stages 11, 12, 13, 14 are illustrated by way of example in FIG. 1. The first 11, second 12, third 13 and fourth 14 triggering stage are arranged successively proceeding from the breakdown structure 10 in the direction of the heavily n-doped main emitter 5.

Each of the triggering stages 11, 12, 13, 14 comprises a heavily n-doped triggering stage emitter 51 embedded in the p-doped base 6, said emitter making contact with a triggering stage electrode 91 arranged on the front side 19 of the semiconductor body 1.

The resistance zone 65 is arranged by way of example between the second and third triggering stages 12 and 13, respectively, in the lateral direction r. An external resistor 30 with a resistance value R.ext arranged outside the semiconductor body 1 is electrically connected in parallel with the resistance zone 65. For the purpose of electrically contact-connecting the resistance zone 65 to the external resistor 30, a first connection location 31 and a second connection location 32 are provided on the semiconductor body 1.

Connecting the resistance zone 65 and the external resistor 30 in parallel gives rise to a total protective resistance R.tot which is calculated as follows:

$$R . tot = \frac{R . int \cdot R . ext}{R . int + R . ext} \qquad ( 1 )$$

The value R.tot of the total protective resistance at room temperature (293 K) amounts to preferably between 10Ω and 500Ω, particularly preferably between 80Ω and 120Ω.

Thus, for a predetermined value R.tot of the protective resistance and for a specific value R.int, preferably between 20Ω and 1000Ω of the resistance of the resistance zone 65, the required value R.ext of the external resistor 30 can be determined from equation (1).

Presupposing that, in a specific temperature range, the magnitude of the temperature sensitivity of the external resistor 30 is less than the magnitude of the temperature sensitivity of the resistance zone 65, the total resistance R.tot also has a temperature sensitivity which is less than the temperature sensitivity of the resistance zone 65.

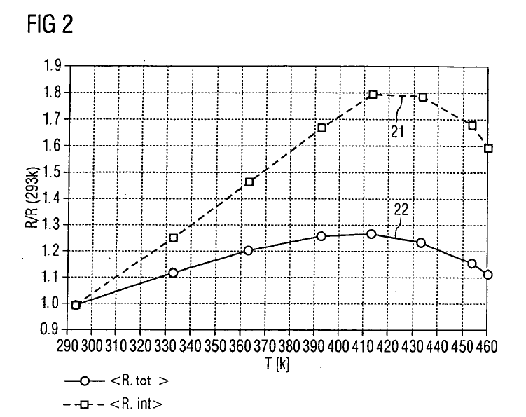

FIG. 2 shows the profile of a total electrical resistance R.tot formed in this way as a function of the temperature in comparison with the profile of a protective resistance formed merely by a resistance zone.

A dashed first curve 21 shows the profile of the resistance value R.int of a resistance zone of a thyristor in accordance with the prior art, that is to say in which the protective resistance is formed merely from the resistance zone, as a function of the temperature. The first curve 21 is normalized to the resistance value R at room temperature (293 K).

In the temperature interval illustrated, which in the present exemplary embodiment extends from a minimum temperature at 293 K (room temperature) up to a maximum temperature of 460 K, the resistance R.int of the resistance zone rises up to a temperature of approximately 410 K and then falls again as the temperature rises further. The ratio between the maximum value of the resistance R.int of the resistance zone in the temperature interval and its minimum value at room temperature (293 K) of the resistance R.int in the temperature interval under consideration is approximately 1.8 in this case.

In comparison with this, the second, solid curve 22 shows the profile of the resistance R.tot of a protective resistance formed from a resistance zone and an external resistor R.ext electrically connected in parallel therewith. The second curve 22 was also normalized to the value of the total resistance R.tot (293 K) at room temperature. It was furthermore assumed for this illustration that the value R.ext of the external resistor is constant independently of its temperature T.

Since the protective resistance would be reduced by simply connecting an external resistor in parallel, in the case of the second curve 22 the lateral resistance of the internal resistance zone was increased to an extent such that the value of the protective resistance R.tot at room temperature corresponds to the resistance value of the protective resistance R.int at room temperature in the case of the first curve 21.

As shown by the profile of the second curve 22, in this case the ratio between the maximum value and the minimum value of the resistance R.tot in the temperature interval from 290 K to 460 K already considered above amounts to approximately 1.27, which corresponds to a significantly lower temperature dependence of the protective resistance than in the case of the first curve 21.

In accordance with one preferred embodiment of the invention, the total resistance R.tot of the external resistor and the resistance zone electrically connected in parallel therewith, in the temperature range of between 300 K and 450 K, deviates preferably not more than 50%, particularly preferably not more than 30% from the total resistance R.tot at a temperature of 300 K.

In order to support the effectiveness of the external resistor with regard to reducing the temperature dependence of the protective resistance and to further reduce the temperature dependence of the internal resistance R.int of the resistance zone 65, particles, for example helium ions, silicon ions, electrons or other, preferably non-doping, particles, may be radiated into the resistance zone 65. In the irradiated regions this gives rise to defects at which the charge carriers of the resistance zone are scattered, as a result of which the mobility of said charge carriers is reduced.

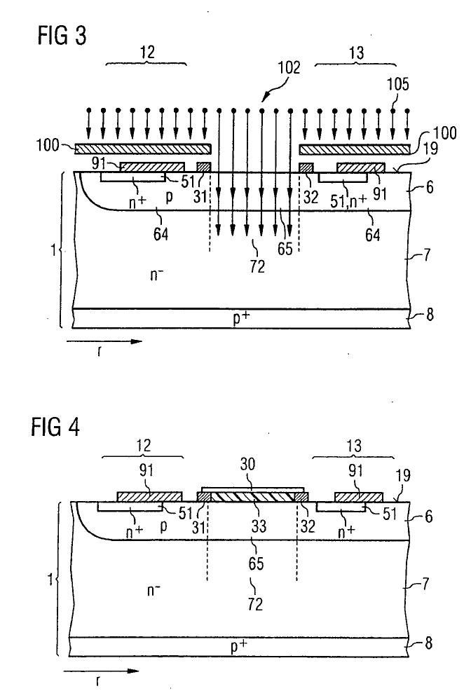

As is illustrated in FIG. 3, particles 105 are radiated into the resistance zone 65 preferably by means of masked irradiation proceeding from the front side 19 of the semiconductor body 1. A mask 100 having one or more openings 102 is used for this purpose. An opening 102 of the mask 100 is arranged opposite the resistance zone 65. During the irradiation process, particles 105 pass through the opening 102 of the mask 100 and penetrate, depending on their energy, to a specific penetration depth into the semiconductor body 1, where they produce the defects mentioned.

In this way, it is possible to reduce the mobility of the charge carriers in the resistance zone 65, as is already known from the prior art.

Moreover, the invention provides for particles 105 also to be radiated into a section 72 of the n-doped base 7 that is arranged below the resistance zone 65, and for the mobility of the charge carriers thereby to be reduced in said section 72. For the irradiation of the section 72 it is possible to use the same type of particles 105 as used for the irradiation of the resistance zone 65. Electrons are particularly suitable since a particularly high penetration depth can be achieved with them, so that the irradiated region 72 may, if appropriate, extend over the entire depth of the component as far as the opposite anode contact.

The irradiation of the resistance zone 65 and of the section 72 is preferably effected during a single irradiation step. Different penetration depths can be achieved for example by means of a corresponding distribution of the energy of the particles 105 radiated in. It is likewise possible to irradiate the resistance zone 65 and the section 72 one after the other in any desired order using identical or different particles 105 having identical or different energy.

The temperature dependence of a protective resistance formed by the resistance R.int is reduced by the introduction of particles 105 into the resistance zone 65 and into the section 72 of the n-doped base 7. The measure of introducing particles 105 into the resistance zone 65 and/or into the section 72 of the n-doped base 7 may be combined in a particularly advantageous manner with the use of an external resistor, as described in detail above. For reasons of clarity, the illustration of an external resistor has been dispensed with in FIG. 3.

The invention provides various variants for the purpose of electrically contact-connecting an external resistor to a resistance zone. As explained above, a first connection location 31 and a second connection location 32 are provided for making electrical contact with the resistance zone 65. The connection locations 31, 32 are preferably formed as metallizations of the semiconductor body 1 and are arranged on the front side 19 thereof. The resistance zone 65 extends in the lateral direction r approximately between the mutually facing sides of the connection locations 31, 32.

The realization of an external resistor can be realized in a multiplicity of variants.

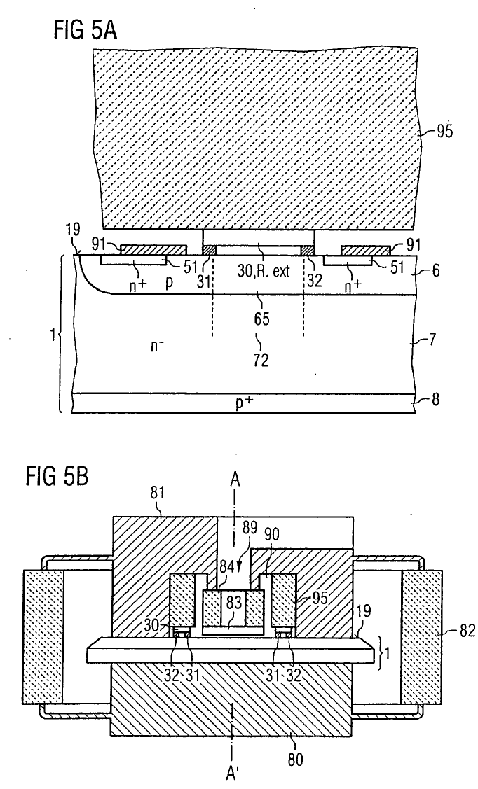

A first variant illustrated in FIG. 4 uses an external resistor 30 that is preferably formed as a film resistor and electrically connects the first and second connection locations 31, 32 to one another. A film resistor of this type is preferably spaced apart from the semiconductor body 1 by means of an insulator 33 and is advantageously fixedly connected to said semiconductor body. The insulator 33 may be formed from a ceramic or an oxide, for example.

If the resistance R.ext of the external resistor 30 has, in a specific temperature interval, a temperature coefficient whose magnitude is less than the magnitude of the temperature coefficient of the resistance zone 65, then it is advantageous for the external resistor 30 to be thermally insulated as well as possible from the semiconductor body 1.

If, on the other hand, the external resistor 30 has, in a specific temperature interval, a temperature coefficient whose magnitude is greater than the magnitude of the temperature coefficient of the resistance zone 65, then it is advantageous for the external resistor 30 to be coupled to the semiconductor body 1 in a manner exhibiting the best possible thermal conductivity.

An external resistor 30 may be produced for example by vapor deposition, sputtering, deposition, screen printing or similar known methods. Examples of suitable materials for the external resistor 30 are constantan, manganin, carbon composition resistors, etc. A resistor based on polycrystalline silicon is also suitable since its resistance generally has a significantly lower temperature coefficient than monocrystalline silicon.

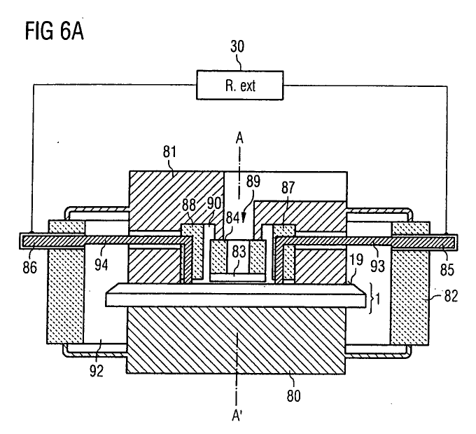

A further variant for realizing an external resistor 30 is shown in FIG. 5a. In the same way as in FIG. 4, in the exemplary embodiment in accordance with FIG. 5a, too, the resistance zone 65 is contact-connected by means of a first and second connection location 31, 32, respectively. The external resistor 30 in accordance with FIG. 5a is formed as a film resistor like the external resistor 30 in accordance with FIG. 4.

However, the external resistor 30 in accordance with FIG. 5a is preferably embodied as a coating of a ceramic element 95, via which the heat loss arising in the external resistor 30 can be dissipated. In order to be able to adapt the resistance value in the required manner, provision is made, in particular, for providing the ceramic element 95 with one or more indentations or the like in order to enlarge the area over which the coating—that is to say the resistor 30—extends. Provision is furthermore made for arranging the coating in meandering fashion on the surface of the ceramic element 95.

The external resistor 30 that is fixedly connected to the ceramic element 95 is preferably not fixedly connected to the connection locations 31, 32, but rather only electrically contact-connected to the latter. In particular, at the ceramic element 95 provision may be made of spring contacts (not specifically illustrated in FIG. 5a), one or more of which make contact with the first connection location 31 and one or more others of which make contact with the second connection location 32. The spring elements making contact with the first 31 and the second 32 connection location are electrically connected to one another by means of the external resistor 30, so that the external resistor 30 is connected between the connection locations 31, 32 in the case of proper contact-connection of the spring elements.

FIG. 5b shows an overview illustration through a thyristor with an external resistor 30 in accordance with FIG. 5a, said thyristor not being illustrated to scale. The semiconductor body 1 of the thyristor has a housing, which in particular comprises an anode 80 and a cathode 81, which are preferably formed from copper or a copper alloy. The anode 80 makes contact with the p-doped emitter 8 and the cathode 81 makes contact with the n-doped main emitter 5. Furthermore, the housing has an insulator 82, which electrically insulates the anode 80 and the cathode 81 from one another.

A light channel 89 is formed in the cathode 81, and light, in particular infrared light, can enter through said light channel onto the breakdown structure 10 of the semiconductor body 1. In order to prevent the ingress of moisture and dirt, the light channel is closed off with a light window 83, which is connected to the cathode 81 via a ceramic insulator 84. The cathode 81, the front side 19 of the semiconductor body 1, the light window 83 and also the ceramic insulator 84 enclose a chamber 90, in which one or more ceramic elements 95 in accordance with FIG. 5a may be arranged. A ceramic element 95 is preferably in good thermal contact with the cathode 81, so that the heat loss of the external resistor 30 can be dissipated to the cathode 81 via the ceramic body 95. For this purpose, the ceramic element 95 is preferably adhesively bonded to the anode 81 and is in good thermal contact with the latter, so that the heat loss that arises can be dissipated further to the outside. The ceramic element 95 and/or the external resistor are preferably embodied in ring form and are arranged rotationally symmetrically with respect to the axis A-A′.

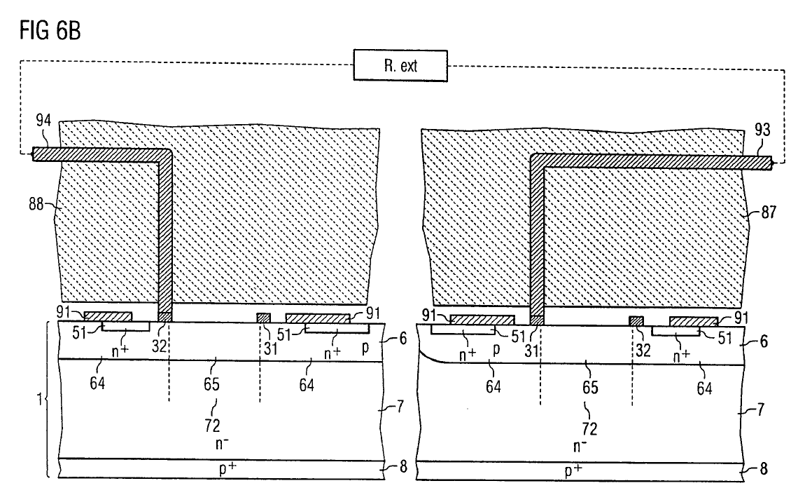

A further variant for making electrical contact with an external resistor 30 is illustrated in FIG. 6a. In this case, too, the semiconductor body 1 is surrounded by a housing, which essentially comprises the same components as the housing illustrated in FIG. 5b. Unlike in the thyristor illustrated in FIGS. 5a and 5b, however, the external resistor 30 is arranged outside the thyristor housing. For this purpose, the thyristor housing is provided with connection contacts 85, 86, of which the first connection contact 85 makes electrical contact with the first connection location 31 and the second connection contact 86 makes electrical contact with the second connection location 32. In this case, the connection contacts 85, 86 are led to the outside through openings introduced into the cathode 81 and also through openings in the ceramic insulator 82. The leadthrough of the connection contacts 85, 86 in particular through the openings of the ceramic insulator 82 is formed in hermetically sealed fashion in order to prevent dirt and moisture from penetrating into the interior space 92 and the chamber 90 of the thyristor housing.

The external resistor 30 can be connected to the connection contacts 85, 86—which are led out from the thyristor housing—in a simple manner by means of a first 93 and second 94 connection conductor, respectively. In order to make contact with the external resistor 30, the connection contacts 85, 86 that are led to the outside may be formed e.g. as plug, screw, clamping or soldering contacts.

For electrical insulation, the first connection conductor 93 is led through a ceramic sleeve 87 and the second connection conductor 94 is led through a second ceramic sleeve 88. The ceramic sleeves 87, 88 are preferably adhesively bonded to the anode 81 and are in good thermal contact with the latter, so that heat loss that arises can be dissipated further to the outside.

Irrespective of the specific variant from among those described above in which an external resistor 30 of a thyristor has been realized, it is advantageous if the external resistor has specific features.

The electrical resistance of a semiconductor and thus in particular also of the resistance zone of a thyristor have a negative temperature coefficient at higher temperatures, that is to say that the resistance decreases as the temperature increases.

Therefore, it is advantageous if an external resistor which is connected in parallel with a resistance zone according to the explanations in accordance with FIG. 1 is constant at least over a specific temperature range or has an opposite temperature coefficient to the temperature coefficient of the resistance zone, so that the protective resistance, in the temperature range that is relevant to the thyristor, is as far as possible independent of temperature or has only a comparatively small positive temperature coefficient. It must be taken into consideration in this case that the temperatures of the external resistor and of the resistance zone may differ to a greater or lesser extent in particular depending on the location and type of fitting of the external resistor and also on the heat loss arising in the thyristor.

In particular resistors having positive temperature coefficients (PTC thermistors) can be used as external resistors 30. By way of example, standard power resistors such as carbon composition resistors are suitable as external resistors 30. Resistors based on polycrystalline silicon are also well suited.

The temperature fluctuations of an external resistor arranged outside the thyristor housing can be limited in a simple manner by cooling the external resistor by means of water or air, for example, or by thermally coupling it to a heat accumulator having a high heat capacity. It is likewise also possible to actively cool the external resistor or to regulate its temperature, e.g. by means of a Peltier element.

By virtue of the fact that the external resistor 30 can be fitted in a manner spaced apart spatially from the semiconductor body 1 or from the housing of the thyristor, it can be thermally decoupled therefrom in a simple manner. A possible temperature dependence of the external resistor 30 is thus less relevant than if the external resistor 30 is coupled to the housing or the semiconductor body 1 of the thyristor 1.

FIG. 6b shows an enlarged detail from the thyristor illustrated in FIG. 6a. The first connection location 31 and the second connection location 32 are embodied in ring form or are embodied essentially in ring form. In this case, the first connection conductor 93 makes contact with the first connection location 31 and the second connection conductor 94 makes contact with the second connection location 32. The contact-connection is preferably effected by means of spring contacts which are not specifically illustrated, such as are known, for example from contact-connecting gate connections of a thyristor.

In all the exemplary embodiments above, the connection contacts 31, 32 may be formed as metallizations arranged on the front side 19 of the semiconductor body 1. Instead of performing a dedicated metallization for the connection contact 31 facing the breakdown structure 10 (in this respect, cf. in particular FIG. 1), it is also possible to use the triggering stage electrode 91 of the triggering stage 12 that is closest to the resistance zone 65 in the direction of the breakdown structure 10, or an already existing gate metallization provided for the electrical triggering of the thyristor.

The resistance zones described previously have been illustrated by way of example as protective resistance for limiting the current of a triggering stage (amplifying gate stage) in a thyristor. However, other sections of the semiconductor body of a thyristor or of another semiconductor component may likewise also be formed as a resistance zone, so that the temperature dependence of the electrical resistance of such a resistance zone can be correspondingly improved by means of an external resistor arranged outside the semiconductor body.

Resistance zones in the p-doped base of thyristors whose resistance value depends on the lateral direction with regard to the crystal structure of the semiconductor body are in particular also then used in order to compensate for differences in the triggering propagation speed that are brought about by the crystal structure. The electrical resistances of such resistance zones also exhibit a temperature dependence which can be reduced by means of an external resistor arranged in the manner described.

### LIST OF REFERENCE SYMBOLS

1 Semiconductor body
5 n-doped main emitter
6 p-doped base
7 n-doped base
8 p-doped emitter
9 Emitter electrode
10 Breakdown structure
11 First triggering stage
12 Second triggering stage
13 Third triggering stage
14 Fourth triggering stage
19 Front side of the semiconductor body
21 First curve
22 Second curve
29 Internal resistor
30 External resistor
31 First connection location
32 Second connection location
33 Insulator
51 Triggering stage emitter
61 Section of the p-doped base
62 Section of the p-doped base
63 Section of the p-doped base
64 Section of the p-doped base
65 Resistance zone
71 Section of the n-doped base
72 Section of the n-doped base
80 Anode
81 Cathode
82 Ceramic insulator
83 Light window
84 Ceramic insulator
85 First connection contact of the thyristor housing
86 Second connection contact of the thyristor housing
87 First ceramic sleeve
88 Second ceramic sleeve
89 Light channel
90 Chamber
91 Triggering stage electrode
92 Interior space
93 First connection conductor
94 Second connection conductor
95 Ceramic element
100 Mask
102 Mask opening
105 Particles
r Lateral direction
A-A′ Axis
R.int Resistance value of the internal resistor
R.ext Resistance value of the external resistor
R.tot Total resistance
T Temperature

What we claim is:

1. A thyristor comprising:
a semiconductor body, wherein a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction, and
an external resistor arranged outside the semiconductor body and electrically connected in parallel with the resistance zone, the external resistor and the resistance zone in each case having a temperature coefficient, and, in a specific temperature range, the magnitude of the temperature coefficient of the external resistor being less than the magnitude of the temperature coefficient of the resistance zone.

2. A thyristor according to claim 1, wherein the temperature coefficient of the external resistor and the temperature coefficient of the resistance zone have different signs in the specific temperature range.

3. A thyristor according to claim 1, wherein the temperature range extends from 300 K to 450 K.

4. A thyristor according to claim 1, wherein the external resistor is constant in the temperature range of between 300 K and 450 K or does not deviate more than 50% from its value at 300 K.

5. A thyristor according to claim 1, wherein the resistance zone and the external resistor electrically connected in parallel therewith have a total resistance which, in the temperature range of between 300 K and 450 K, deviates by at most 50% from its value at 300 K.

6. A thyristor according to claim 5, wherein the resistance zone and the external resistor electrically connected in parallel therewith have a total resistance which, in the temperature range of between 300 K and 450 K, deviates by at most 30% from its value at 300 K.

7. A thyristor according to claim 1, wherein the resistance zone and the external resistor electrically connected in parallel therewith have a total resistance which amounts to between 10Ω and 500Ω at a temperature of 293 K.

8. A thyristor according to claim 7, wherein the resistance zone and the external resistor electrically connected in parallel therewith have a total resistance which amounts to between 80Ω and 120Ω at a temperature of 293 K.

9. A thyristor according to claim 1, wherein the resistance zone has an electrical resistance which amounts to between 20Ω and 1000Ω at a temperature of 293 K.

10. A thyristor according to claim 1, wherein the external resistor comprises at least one of the materials constantan, manganin or polycrystalline silicon or is formed as a carbon composition resistor.

11. A thyristor according to claim 1, wherein the mobility of the charge carriers in the resistance zone is reduced on account of particles being radiated into the resistance zone.

12. A thyristor according to claim 1, wherein in a section of the n-doped base that is arranged below the resistance zone, the mobility of the charge carriers is reduced on account of particles being radiated into said section of the n-doped base.

13. A thyristor according to claim 1, wherein the external resistor is arranged on the semiconductor body and is fixedly connected to the latter.

14. A thyristor according to claim 1, wherein the external resistor is arranged on a ceramic element.

15. A thyristor according to claim 1, comprising a housing, in which the semiconductor body is arranged, the external resistor being arranged outside the housing.

16. A thyristor comprising:
a semiconductor body, wherein a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction,
two connection locations for making electrical contact with the resistance zone, said connection locations being spaced apart from one another in the lateral direction, and
a housing enclosing the semiconductor body, from which housing are led two connection contacts, each of which are electrically conductively connected to a respective one of the connection locations and which are provided for the connection of an external resistor arranged outside the housing.

17. A thyristor according to claim 16, wherein the resistance zone has an electrical resistance which amounts to between 20Ω and 1000Ω at a temperature of 293 K.

18. A thyristor according to claim 16, wherein an external electrical resistor is connected to the connection contacts and is electrically connected in parallel with the resistance zone.

19. A thyristor according to claim 16, wherein the resistance zone has an electrical resistance which amounts to between 20Ω and 1000Ω at a temperature of 293 K.

20. A thyristor according to claim 16, wherein the mobility of the charge carriers in the resistance zone is reduced on account of particles being radiated into the resistance zone.

21. A thyristor according to claim 16, wherein in a section of the n-doped base that is arranged below the resistance zone, the mobility of the charge carriers is reduced on account of particles being radiated into said section of the n-doped base.

22. A method for producing a thyristor, comprising the following method steps of:
providing a semiconductor body, in which a p-doped emitter, an n-doped base, a p-doped base and an n-doped main emitter are arranged successively in a vertical direction, the p-doped base having a resistance zone with a predetermined electrical resistance extending in a lateral direction perpendicular to the vertical direction, and
connecting an external electrical resistor arranged outside the semiconductor body in parallel with the resistance zone, so that the resistance zone and the external resistor form a total electrical resistance which, in a specific temperature range, has a temperature coefficient whose magnitude is less than the temperature coefficient of the resistance zone in said temperature range.

23. A method according to claim 22, wherein the external resistor has, in the specific temperature range, a temperature coefficient whose magnitude is less than the temperature coefficient of the resistance zone in said temperature interval.

24. A method according to claim 22, wherein the temperature range extends from 300 K to 450 K.

25. A method according to claim 22, wherein the electrical resistance of the resistance zone is increased.

26. A method according to claim 25, wherein for the purpose of increasing the electrical resistance of the resistance zone particles are radiated into the resistance zone.

27. A method according to claim 25, wherein particles are radiated into a section of the n-doped base that is arranged below the resistance zone.

28. A method according to claim 22, wherein the electrical resistance of the resistance zone is reduced.
